(19) United States
(12) Patent Application Publication
(10) Pub. No.: US 2026/0124821 A1
(43) Pub. Date: May 7, 2026

(54) COMPOSITE COPPER FOIL AND MANUFACTURING METHOD THEREOF

(71) Applicant: NAN YA PLASTICS CORPORATION, Taipei City (TW)

(72) Inventors: Ching-Yao Yuan, Taipei City (TW); Wei-Sheng Cheng, Taipei City (TW); Wen Ta Cheng, Taipei City (TW); Chung Ni Wu, Taipei City (TW)

(73) Assignee: NAN YA PLASTICS CORPORATION, Taipei City (TW)

(21) Appl. No.: 18/967,570

(22) Filed: Dec. 3, 2024

(30) Foreign Application Priority Data
Nov. 5, 2024 (TW) 113142314

(51) Int. Cl. B32B 15/01; B32B 7/12; B32B 15/20

(52) U.S. Cl. CPC B32B 15/018; B32B 7/12; B32B 15/20; H01B 5/14; H05K 3/44; B32B 2250/02; B32B 2307/304; B32B 2307/7376; B32B 2311/12

(57) ABSTRACT

Provided is a composite copper foil including a first copper foil, a second copper foil, and an insulating bonding layer. The insulating bonding layer is disposed between the first copper foil and the second copper foil. A thickness of the insulating bonding layer is less than 5 micrometers.

### CROSS-REFERENCE TO RELATED APPLICATION

This application claims the priority benefit of Taiwan application serial no. 113142314, filed on Nov. 5, 2024. The entirety of the above-mentioned patent application is hereby incorporated by reference herein and made a part of this specification.

### BACKGROUND

### Technical Field

The disclosure relates to a metal foil and a manufacturing method thereof, and particularly relates to a composite copper foil and a manufacturing method thereof.

### Description of Related Art

The conventional manufacturing method of composite copper foil involves first providing a polymer film (such as a polyester (PET) film or a polyimide (PI) film). Then, a first conductive film (commonly referred to as a conductive seed layer) is formed on both sides of the polymer film by sputtering. Afterward, the first conductive film is thickened through electroplating to form a second conductive film (commonly referred to as an electroplated layer). The composite copper foil formed by the method is usually limited by the thickness of the polymer film and the corresponding formation method of the conductive film, making it difficult to effectively reduce the overall thickness (for example, at least 6 micrometers). In addition, if a thinner polymer film is directly used for double-sided plating, it may not be able to effectively insulate due to penetration caused by plated atoms, plated particles, and/or plasma during the plating (such as sputtering or similar plasma deposition plating) process.

Therefore, how to make composite copper foil with thinner thickness and still have good quality is a research topic.

### SUMMARY

The disclosure provides a composite copper foil and a manufacturing method thereof. The structure and/or the manufacturing method of the composite copper foil is relatively simple, and the thickness can be relatively thin, but the quality is still good.

The manufacturing method of the composite copper foil of the disclosure includes the following steps: providing a first copper foil and a second copper foil with separate structures; forming an insulating bonding material between the first copper foil and the second copper foil; forming the insulating bonding material into an insulating bonding layer, so that the first copper foil and the second copper foil are bonded through the insulating bonding layer.

The composite copper foil of the disclosure includes a first copper foil, a second copper foil, and an insulating bonding layer. The insulating bonding layer is disposed between the first copper foil and the second copper foil. The thickness of the insulating bonding layer is less than 5 micrometers.

Based on the above, the manufacturing method and/or the structure of the composite copper foil of the disclosure can be relatively simple, and the thickness can be relatively thin, but the quality is still good.

### BRIEF DESCRIPTION OF THE DRAWINGS

FIG. 1 is a partial flow chart of part of a manufacturing method of a composite copper foil according to an embodiment of the disclosure.

FIG. 2A to FIG. 2E are partial side views of part of the manufacturing method of the composite copper foil according to an embodiment of the disclosure.

### DESCRIPTION OF THE EMBODIMENTS

In the following detailed description, for purposes of illustration and not limitation, example embodiments are set forth disclosing specific details in order to provide a thorough understanding of the various principles of the disclosure. However, it will be apparent to one of ordinary skill in the art, having the benefit of this disclosure, that the disclosure may be practiced in other embodiments that depart from the specific details disclosed herein. Additionally, descriptions of well-known devices, methods, and materials may be omitted so as not to obscure the various principles of the disclosure.

A range may be expressed herein as from “approximately” one specific value to “approximately” another specific value, and may also be expressed directly as one specific value and/or to another specific value. In expressing ranges, another embodiment includes from the one particular value and/or to another particular value. Similarly, when a value is expressed as an approximation by use of the antecedent “approximately”, it should be understood that the particular value forms another embodiment. It will be further understood that the endpoints of each range are clearly related or independent of the other endpoints.

In the document, non-limiting terms (such as: may, can, for example, or other similar terms) refer to not mandatory or optional implementation, inclusion, addition, or existence.

Unless otherwise defined, all terms (including technical and scientific terms) used herein have the same meaning as commonly understood by one of ordinary skill in the art to which this disclosure belongs. It will also be understood that terms (such as defined in commonly used dictionaries) shall be construed to have a meaning consistent with the meaning in the relevant technical context and shall not be construed in an idealized or overly formal sense, except when being clearly defined this way in the document.

In the drawings, the thickness of some film layers may be enlarged for clarity.

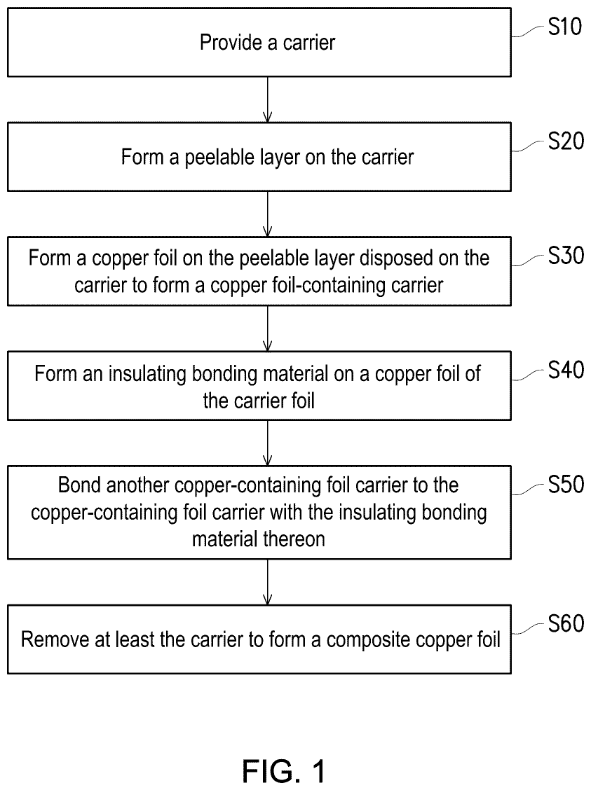

FIG. 1 is a partial flow chart of part of a manufacturing method of a composite copper foil according to an embodiment of the disclosure.

Referring to FIG. 1, a composite copper foil manufacturing method according to an embodiment of the disclosure may include the following steps.

Step S10: A carrier is provided (may be referred to as a first carrier).

Step S20: A peelable layer (may be referred to as a first peelable layer) is formed on the carrier (such as the first carrier).

Step S30: A copper foil (may be referred to as a first copper foil) is formed on the peelable layer disposed on the carrier (such as on the first peelable layer disposed on the first carrier) to form a copper foil-containing carrier including copper foil (for example: including the peelable layer on the carrier and the copper foil on the peelable layer; may be referred to as a first copper foil-containing carrier).

Step S40: An insulating bonding material is formed on a copper foil of the copper foil-containing carrier (such as the copper foil of the first copper foil-containing carrier).

Step S50: A copper foil of another copper foil-containing carrier (such as a copper foil of another copper foil-containing carrier different from the first copper foil-containing carrier; may be referred to as a second copper foil-containing carrier) is bonded to the copper foil-containing carrier with the insulating bonding material thereon (such as: the first copper foil-containing carrier with the insulating bonding material formed on the copper foil).

Step S60: At least the carrier is removed to form the composite copper foil.

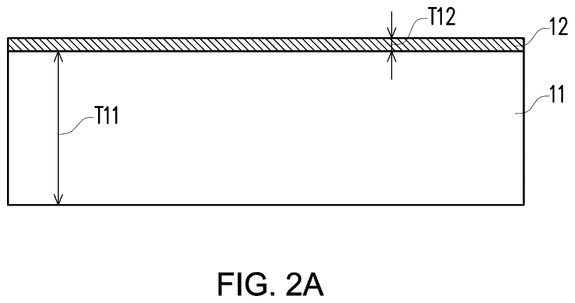

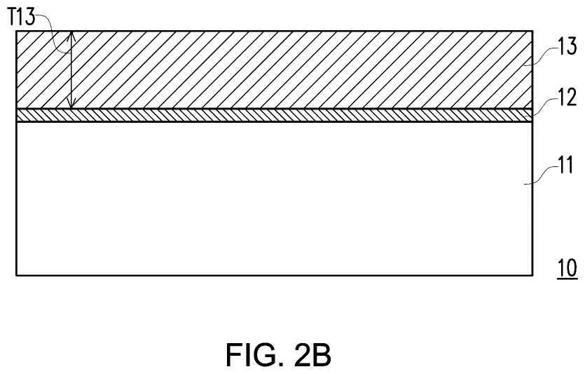

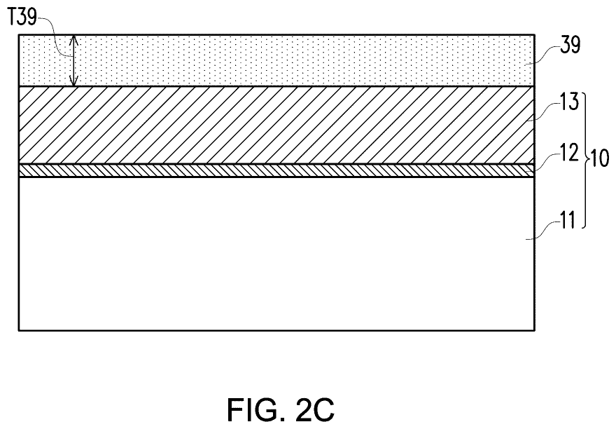

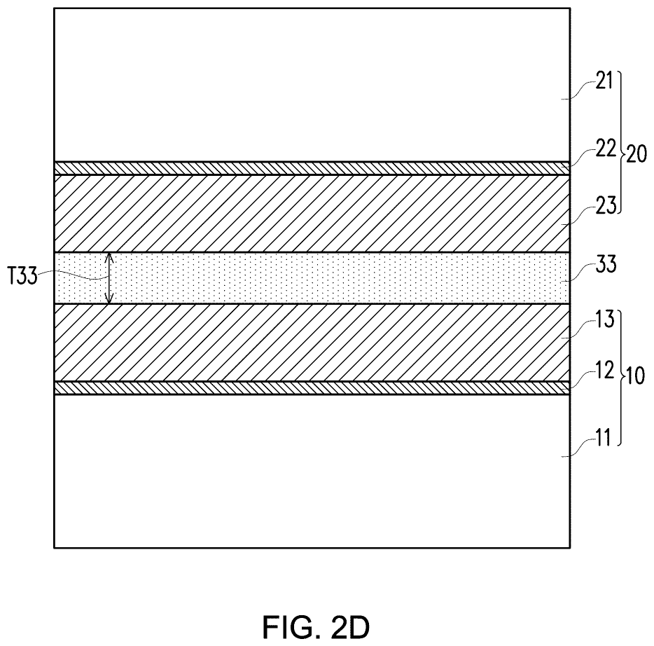

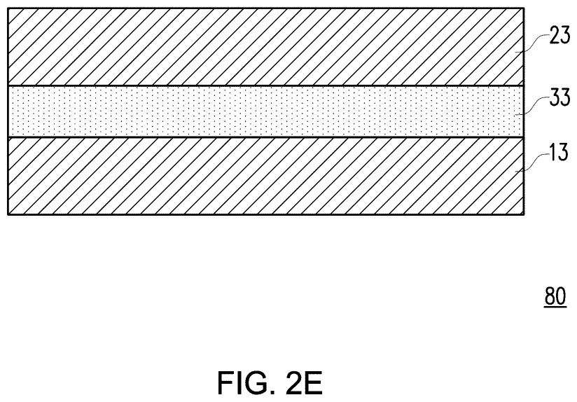

FIG. 2A to FIG. 2E are partial side views of the manufacturing method of the composite copper foil according to an embodiment of the disclosure. In an embodiment, the steps shown in FIG. 1 may be shown in FIG. 2A to FIG. 2E.

Referring to FIG. 2A, a first carrier 11 is provided. The disclosure has no particular limitation on the material or the thickness of the first carrier 11, as long as an appropriate film layer may be formed on the first carrier 11 so that the first carrier 11 is adapted to carry the film layer formed thereon.

In an embodiment, the first carrier 11 may be made of conductive material, flexible material, material that can be used multiple times and/or is recyclable. In an embodiment, the first carrier 11 may be a sheet-shaped, plate-shaped, or block-shaped metal material; for example, copper material, aluminum material, or a combination of the above (such as aluminum material with copper plated surface). In a preferred embodiment, the first carrier 11 may be copper material (such as copper sheet, copper plate, or copper block), the possible reason why it is preferred is that the copper material can have the same or similar coefficient of thermal expansion (CTE) and/or the same or similar physical or chemical properties as the copper layer (such as a copper plating layer or a copper foil) subsequently formed thereon.

In an embodiment, a thickness T11 of the first carrier 11 may be approximately 10 micrometers (μm) to approximately 30 micrometers.

Referring to FIG. 2A still, a first peelable layer 12 is formed on the first carrier 11. The first peelable layer 12 may be temporarily bonded to the first carrier 11, and may be removed and/or separated from the first carrier 11 by suitable means in subsequent suitable steps.

In a preferred embodiment, the first peelable layer 12 may be formed by inorganic metal salts. The possible reason why it is preferred is that the first peelable layer 12 formed by the inorganic metal salts has a good temporary bonding to the first carrier 11 and the subsequently formed film layers (such as the copper foil).

In an embodiment, the first peelable layer 12 may be referred to as an inorganic peelable layer. In an embodiment, the first peelable layer 12 contains substantially no organic matter.

In an embodiment, the first peelable layer 12 may be formed on the first carrier 11 by electroplating. The electrolyte solution used in electroplating may be an electrolyte compound containing manganese, cobalt, nickel, molybdenum, iron, and/or tungsten, for example, may be sulfate, nitrate, phosphate, or chloride of manganese, cobalt, nickel, molybdenum, iron, and/or tungsten, salts derived from the oxides of the foregoing metals, and/or hydrates of the foregoing salts. In an embodiment, the manganese-containing compound may include, for example, manganese sulfate, manganese nitrate, manganese phosphate, or manganese chloride. In an embodiment, the cobalt-containing compound may include, for example, cobalt sulfate, cobalt nitrate, cobalt phosphate, cobalt chloride, or cobaltous chloride. In an embodiment, the nickel-containing compound may include, for example, nickel sulfate, nickel ammonium sulfate, nickel nitrate, or nickel chloride. In an embodiment, the molybdenum-containing compound may include, for example, sodium molybdate, potassium molybdate, molybdenum disulfide, molybdenum nitrate, molybdenum phosphate, or molybdenum chloride. In an embodiment, the iron-containing compound may include, for example, iron sulfate, iron nitrate, iron phosphate, or iron chloride. In an embodiment, the tungsten-containing compound may include, for example, sodium tungstate or potassium tungstate. In an embodiment, the solvent of the electrolyte may include water.

In an embodiment, the electrolyte can have a corresponding pH value by adding an acidic agent or an alkali agent. In an embodiment, the pH value of the electrolyte may be approximately 2.5 to 4.5. In an embodiment, the added acid agent may include sulfuric acid, nitric acid, hydrochloric acid, or phosphoric acid.

In an embodiment, the temperature of electrolysis may be approximately in the range of 20° C. to 60° C. In an embodiment, the current density of electrolysis may be approximately in the range of 0.1 A/dm² to 50 A/dm².

In an embodiment, the concentration of metal ions to be plated in the electrolyte may be approximately 0.005M (molar, mol/L) to 0.5M.

In an embodiment, the conductivity of the electrolyte may be adjusted by adding other non-plated electrolytes. The metal contained in the “non-plated electrolyte” is basically not reduced and is plated on the first carrier 11. The “non-plated electrolyte” may include, for example, the corresponding potassium salt or sodium salt.

In an embodiment, the electroplating time may be adjusted according to requirements (such as corresponding thickness) or corresponding conditions (such as current density, plating temperature, and/or metal ion concentration to be plated).

In an embodiment, the electroplated layer formed on the first carrier 11 may basically be referred to as the first peelable layer 12.

In an embodiment, before forming the first peelable layer 12 on the first carrier 11, the first carrier 11 may be appropriately pre-treated. The pretreatment may include but is not limited to: acid pickling, alkali cleaning, degreasing, and/or electrolytic cleaning, so that the first carrier 11 has an outer surface that is cleaner and/or easier for the first peelable layer 12 to adhere to.

In an embodiment, after electroplating, preferably, the first carrier 11 and the electroplated layer disposed thereon may be appropriately heated to form a corresponding first peelable layer 12. One possible reason why it is preferred is that it may be possible to promote the metal in the first peelable layer 12 and the metal in the first carrier 11 to form a corresponding eutectic mixture, thereby improving the bonding force between the first peelable layer 12 and the first carrier 11. One possible reason why it is preferred is that it may be possible to promote the oxidation and/or roughening of the outer surface of the first peelable layer 12 (that is, the surface in contact with the first carrier 11 and exposed to the outside), thereby improving the bonding force between the first peelable layer 12 and the subsequently formed film layers (such as the copper foil).

In an embodiment, a thickness T12 of the first peelable layer 12 may be approximately 20 nanometers (nm) to 100 nanometers, preferably, may be approximately 40 nanometers to 60 nanometers.

Referring to FIG. 2B, a first copper foil 13 is formed on the first peelable layer 12 disposed on the first carrier 11 to form a first copper foil-containing carrier 10 including the first copper foil 13.

In an embodiment, the corresponding first copper foil 13 may be formed on the first peelable layer 12 by sputtering, electroplating, electroplating after sputtering, or other suitable or common methods.

In an embodiment, a thickness T11 of the first carrier 11 may be 5 times to 30 times of a thickness T13 of the first copper foil 13. In an embodiment, the thickness T13 of the first copper foil 13 may be 15 times to 50 times of the thickness T12 of the first peelable layer 12.

In an embodiment, the thickness T13 of the first copper foil 13 may be less than 6 micrometers (μm), preferably, less than or approximately equal to 4.5 micrometers, for example, approximately 1 micrometer to 2 micrometers.

In an embodiment, if necessary, the first copper foil-containing carrier 10 including the first copper foil 13 may be cut by suitable means. In an embodiment, if necessary, the first copper foil-containing carrier 10 including the first copper foil 13 may be temporarily stored by suitable means (for example, rolled up).

Referring to FIG. 2C, an insulating bonding material 39 is formed on the first copper foil 13 of the first copper foil-containing carrier 10.

In an embodiment, the insulating bonding material 39 may include epoxy, polyamide (PA), ether polymers (such as polyethersulfone (PES) or polyetheretherketone (PEEK)), polyolefin (such as polyethylene (PE)), ethylene vinyl acetate (EVA), polyimide (PI), or a combination or mixture of the above.

In an embodiment, the corresponding insulating bonding material 39 may be formed on the first copper foil 13 by spraying, roll coating, dipping, spraying, or other suitable methods. In an embodiment, if necessary, the corresponding insulating bonding material 39 may be optionally semi-cured by suitable means (such as heating and/or standing).

Referring to FIG. 2D, a second copper foil-containing carrier 20 is provided, and a second copper foil 23 of the second copper foil-containing carrier 20 is made face to face with the first copper foil 13 of the first carrier foil, so that the second copper foil-containing carrier 20 and the first carrier foil are bonded through the insulating bonding layer 33 through appropriate steps.

In an embodiment, the second copper foil-containing carrier 20 and the first carrier foil may have the same or similar structure (such as thickness or shape), material, and/or formation method. For example, the second copper foil-containing carrier 20 may include a second carrier 21, a second peelable layer 22, and a second copper foil 23; the first carrier foil may include a first carrier 11, a first peelable layer 12, and a first copper foil 13; the second carrier 21 and the first carrier 11 may have the same or similar structure, material, and/or formation method; the second peelable layer 22 and the first peelable layer 12 may have the same or similar structure, material, and/or formation method; and/or, the second copper foil 23 and the first copper foil 13 may have the same or similar structure, material, and/or formation method.

Referring to FIG. 2C and FIG. 2D, in an embodiment, the insulating bonding layer 33 (shown in FIG. 2D) may be formed from the insulating bonding material 39 (shown in FIG. 2C). For example, the second copper foil 23 of the second copper foil-containing carrier 20 may be brought into contact with the insulating bonding material 39 (which may be uncured or semi-cured) on the first copper foil 13; then, the insulating bonding material 39 is cured by suitable means (such as heating, irradiation, and/or standing) to form the insulating bonding layer 33 in contact with and bonding the first copper foil 13 and the second copper foil 23.

In an embodiment, before the insulating bonding material 39 is completely cured, the distance between the first copper foil 13 and the second copper foil 23 may be brought closer but without making contact by suitable means (such as pressing). That is to say, compared with the thickness T39 of the insulating bonding material 39, the thickness T33 of the insulating bonding layer 33 can be relatively thin. In this way, a composite copper foil 80 formed (shown in FIG. 2E) can have a thinner thickness.

In an embodiment, during the process of bringing the distance between the first copper foil 13 and the second copper foil 23 closer (such as the pressing process), the corresponding structure may be placed at a lower pressure (such as less than 1 atmosphere; or, less than 0.1 atmosphere). For example, the process may be performed in a chamber with a lower atmosphere. In this way, the gas between the first copper foil 13 and the second copper foil 23 may be discharged more easily, thereby reducing the number and/or volume of bubbles embedded in the insulating bonding material 39 (or the corresponding insulating bonding layer 33).

In an embodiment, when bringing the distance between the first copper foil 13 and the second copper foil 23 closer, a portion of the insulating bonding material 39 may overflow between the first copper foil 13 and the second copper foil 23. The overflowing portion of the insulating bonding material 39 may be removed by scraping or other suitable means before being cured; and/or the overflowing portion of the insulating bonding material 39 may be removed by cutting or other suitable means after being cured.

In an embodiment, the thickness T33 of the insulating bonding layer 33 may be less than 5 micrometers, preferably, less than or approximately equal to 4.5 micrometers, for example, approximately 2 micrometers to 4.5 micrometers.

In an embodiment, if necessary, the structure shown in FIG. 2D may be appropriately cut. In an embodiment, if necessary, the structure shown in FIG. 2D may be appropriately rolled up.

Referring to FIG. 2D and FIG. 2E, the upper surface of the first copper foil 13 (the upper surface in the drawing) and the lower surface of the second copper foil 23 (the lower surface in the drawing) may be made exposed by suitable means. For example, the first carrier 11 and/or the second carrier 21 may be removed by tearing. Moreover, if a portion of the first peelable layer 12 remains on the upper surface of the first copper foil 13 (at the top in the drawing) and/or a portion of the second peelable layer 22 remains on the lower surface of the second copper foil 23 (at the bottom in the drawing), the remained portion may be removed by etching, wiping, washing, or other suitable means.

After the process, the fabrication of the composite copper foil 80 in this embodiment can be basically completed. The composite copper foil 80 includes the first copper foil 13, the second copper foil 23, and the insulating bonding layer 33. The insulating bonding layer 33 is disposed between the first copper foil 13 and the second copper foil 23. Two opposite sides (such as the upper side and the lower side) of the insulating bonding layer 33 may be in contact with the first copper foil 13 and the second copper foil 23 respectively.

In an embodiment, the thickness of the first copper foil 13 and/or the thickness of the second copper foil 23 may be less than 6 micrometers (μm), preferably, less than or approximately equal to 4.5 micrometers, for example, approximately 1 micrometer to 2 micrometers.

In an embodiment, the insulating bonding layer 33 is made of polymer. In an embodiment, the insulating bonding layer 33 may be a homogeneous material, and the homogeneous material cannot be further separated into different single materials by mechanical methods (such as crushing, shearing, cutting, sawing, and grinding). In an embodiment, the insulating bonding layer 33 may not have an interface formed by different materials. In an embodiment, the insulating bonding layer 33 may not have interfaces formed by different processes (for example, mutual adhesion).

In an embodiment, composite copper foil 80 is formed by the first copper foil 13, the second copper foil 23, and the insulating bonding layer 33. That is to say, the composite copper foil 80 does not have other film layers different from the first copper foil 13, the second copper foil 23, and the insulating bonding layer 33.

In an embodiment, the first copper foil 13 and the second copper foil 23 of the composite copper foil 80 are not formed on the insulating bonding layer 33. That is to say, structurally speaking, the physical first copper foil 13 and the second copper foil 23 are formed first; then, the insulating bonding layer 33 between the first copper foil 13 and the second copper foil 23 is formed by suitable means (for example, the insulating bonding material between the first copper foil 13 and the second copper foil 23 is cured to form the insulating bonding layer 33). Moreover, the insulating bonding layer 33 may be formed as described above, so the thickness of the composite copper foil 80 can be relatively thin (compared to the composite copper foil formed not using the method of the embodiments of the disclosure), but the quality is still good.

### INDUSTRIAL APPLICABILITY

In an embodiment, the composite copper foil 80 may be suitable for the production of electronic components (such as circuit boards). In an embodiment, the composite copper foil 80 may be suitable for electrodes, for example, may be suitable for the production of batteries (such as lithium-ion battery electrodes).

In summary, the manufacturing method and/or the structure of the composite copper foil of the disclosure can be relatively simple, and the thickness can be relatively thin, but the quality is still good.

What is claimed is:

1. A manufacturing method of a composite copper foil, comprising:
providing a first copper foil and a second copper foil with separate structures;
forming an insulating bonding material between the first copper foil and the second copper foil; and
forming the insulating bonding material into an insulating bonding layer, so that the first copper foil and the second copper foil are bonded through the insulating bonding layer.

2. The manufacturing method of the composite copper foil as claimed in claim 1, further comprising:
providing a first carrier having a first peelable layer thereon, wherein the first copper foil is formed on the first peelable layer; and
providing a second carrier having a second peelable layer thereon, wherein the second copper foil is formed on the second peelable layer.

3. The manufacturing method of the composite copper foil as claimed in claim 2, further comprising:
forming the insulating bonding material on at least one of the first copper foil or the second copper foil; and
making the first copper foil face to face with the second copper foil, and making the insulating bonding material disposed between the first copper foil and the second copper foil.

4. The manufacturing method of the composite copper foil as claimed in claim 2, wherein
the first peelable layer and the second peelable layer are inorganic materials; and
the insulating bonding material is an organic material.

5. The manufacturing method of the composite copper foil as claimed in claim 2, wherein a thickness of the first carrier is 5 times to 30 times of a thickness of the first copper foil.

6. The manufacturing method of the composite copper foil as claimed in claim 2, wherein a thickness of the second carrier is 5 times to 30 times of a thickness of the second copper foil.

7. The manufacturing method of the composite copper foil as claimed in claim 2, wherein a thickness of the second carrier is 5 times to 30 times of a thickness of the first copper foil.

8. The manufacturing method of the composite copper foil as claimed in claim 2, wherein a thickness of the first carrier is 5 times to 30 times of a thickness of the second copper foil.

9. The manufacturing method of the composite copper foil as claimed in claim 2, wherein
a thickness of the first carrier is 5 times to 30 times of a thickness of the first copper foil;
a thickness of the second carrier is 5 times to 30 times of a thickness of the second copper foil;
the thickness of the second carrier is 5 times to 30 times of the thickness of the first copper foil; and
the thickness of the first carrier is 5 times to 30 times of the thickness of the second copper foil.

10. The manufacturing method of the composite copper foil as claimed in claim 2, wherein a thickness of the first copper foil is 15 times to 50 times of a thickness of the first peelable layer.

11. The manufacturing method of the composite copper foil as claimed in claim 2, wherein a thickness of the second copper foil is 15 times to 50 times of a thickness of the second peelable layer.

12. The manufacturing method of the composite copper foil as claimed in claim 2, wherein a thickness of the second copper foil is 15 times to 50 times of a thickness of the first peelable layer.

13. The manufacturing method of the composite copper foil as claimed in claim 2, wherein a thickness of the first copper foil is 15 times to 50 times of a thickness of the second peelable layer.

14. The manufacturing method of the composite copper foil as claimed in claim 2, wherein
a thickness of the first copper foil is 15 times to 50 times of a thickness of the first peelable layer;
a thickness of the second copper foil is 15 times to 50 times of a thickness of the second peelable layer;
the thickness of the second copper foil is 15 times to 50 times of the thickness of the first peelable layer; and
the thickness of the first copper foil is 15 times to 50 times of the thickness of the second peelable layer.

15. The manufacturing method of the composite copper foil as claimed in claim 1, further comprising:
curing the insulating bonding material after the insulating bonding material is in contact with the first copper foil and the second copper foil, so as to form the insulating bonding layer.

16. The manufacturing method of the composite copper foil as claimed in claim 1, wherein a thickness of the insulating bonding layer is thinner than a thickness of the insulating bonding material.

17. The manufacturing method of the composite copper foil as claimed in claim 1, wherein a thickness of the insulating bonding layer is less than 5 micrometers.

18. A composite copper foil, comprising:
a first copper foil;
a second copper foil; and
an insulating bonding layer disposed between the first copper foil and the second copper foil, wherein a thickness of the insulating bonding layer is less than 5 micrometers.

19. The composite copper foil as claimed in claim 18 is formed by the first copper foil, the second copper foil, and the insulating bonding layer.
